(19) United States
(12) Patent Application Publication
(10) Pub. No.: US 2011/0300652 A1
(43) Pub. Date: Dec. 8, 2011

(54) NITRIDE SEMICONDUCTOR LIGHT EMITTING DEVICE AND MANUFACTURING METHOD OF THE SAME

(75) Inventors: Seong Eun Park, Suwon (KR); Bang Won OH, Sungnam (KR); Gil Han Park, Sungnam (KR); Min Ho Kim, Suwon (KR); Rak Jun Choi, Suwon (KR); Young Min Park, Suwon (KR); Hee Seok Park, Suwon (KR)

(73) Assignee: Samsung LED Co., Ltd., Gyunggi-do (KR)

(21) Appl. No.: 13/211,107

(22) Filed: Aug. 16, 2011

Related U.S. Application Data
(62) Division of application No. 11/902,396, filed on Sep. 21, 2007.

(30) Foreign Application Priority Data
Sep. 29, 2006 (KR) 10-2006-96180

(51) Int. Cl. H01L 33/60

(52) U.S. Cl. 438/29; 257/E33.062

(57) ABSTRACT

There is provided a nitride semiconductor light emitting device and a manufacturing method of the same. The nitride semiconductor light emitting device including: a substrate for growing a nitride single crystal, the substrate having electrical conductivity; a p-type nitride semiconductor layer formed on the substrate; an active layer formed on the p-type nitride semiconductor layer, the active layer including a plurality of quantum barrier layers and a plurality of quantum well layers deposited alternately on each other; an n-type nitride semiconductor layer formed on the active layer; a p-electrode formed on a bottom of the substrate; and an n-electrode formed on a top of the n-type nitride semiconductor layer.

### CROSS-REFERENCE TO RELATED APPLICATIONS

This application claims the priority of Korean Patent Application No. 2006-0096180 filed on Sep. 29, 2006, in the Korean Intellectual Property Office, the disclosure of which is incorporated herein by reference.

### BACKGROUND OF THE INVENTION

1. Field of the Invention

The present invention relates to a nitride semiconductor light emitting device, and more particularly, to a nitride semiconductor light emitting device in which a p-type nitride semiconductor layer is grown at a high temperature to enhance crystallinity and optical properties, and a manufacturing method of the same.

2. Description of the Related Art

In general, a group III nitride semiconductor can emit light in a broad region ranging from the entire visible light spectrum to ultraviolet ray. Due to this characteristic, the group III nitride semiconductor has been highlighted as a material for manufacturing visible light and ultraviolet ray LEDs configured as alight emitting diode (LED) or a laser diode (LD), and a blue-green optical device. However, a growth substrate satisfying lattice constant and thermal expansion coefficient of the nitride semiconductor has not been commercially viable.

Conventionally, a nitride semiconductor is grown on a sapphire substrate Al₂O₃ of a heterogeneous material by heteroepitaxy using Metal Organic Chemical Vapor Deposition (MOCVD) and Molecular Beam Epitaxy (MBE). But a nitride single crystal is known to have a crystal defect of about 10⁹ to 10¹⁰ cm⁻² due to difference in lattice constant and thermal expansion coefficient between the sapphire substrate and the nitride layer even though a low-temperature nucleation layer is adopted.

Recently to lower crystal defects of the nitride semiconductor, the nitride semiconductor of a homojunction structure has been grown using a GaN substrate. FIGS. 1A through 1C illustrate a conventional method of growing a nitride semiconductor using a GaN substrate.

First, as shown in FIG. 1A, an n-type GaN layer 12, an InGaN active layer 13, and a p-type AlGaN layer 14 are sequentially grown on an n-type GaN substrate 11 by a MOCVD method. Thereafter, heat-treatment is performed to activate a p-type dopant, and a reflective metal layer 15 is deposited on the p-type AlGaN layer 14 as shown in FIG. 1B. Then, as shown in FIG. 1C, an n-electrode 16 is deposited on the reflective metal layer and a p-electrode 17 is deposited on the n-type GaN substrate.

However, in a case where the n-type GaN substrate 11 is employed as described above, dopant atoms may disadvantageously migrate to the InGaN active layer when the p-type AlGaN layer 14 is grown at a high temperature. Therefore, the p-type AlGaN layer 14 is required to grow at a low temperature up to 950□. Here, the p-type AlGaN layer grown at a temperature up to 950□ is degraded in crystallinity and optical properties. This accordingly deteriorates performance of the nitride semiconductor light emitting device.

Also, the heat treatment for activating the p-type dopant necessitates additional rapid thermal annealing (RTA) equipment, thereby complicating an overall process.

### SUMMARY OF THE INVENTION

An aspect of the present invention provides a nitride semiconductor light emitting device in which a nitride crystal is grown at a high temperature, thereby achieving high crystallinity and optical properties.

An aspect of the present invention also provides a method of manufacturing a nitride semiconductor light emitting device in which a p-type nitride semiconductor layer is heat-treated in a simple process and an n-type nitride semiconductor layer is grown to a small thickness to reduce manufacturing time.

According to an aspect of the present invention, there is provided a nitride semiconductor light emitting device including: a substrate for growing a nitride single crystal, the substrate having electrical conductivity; a p-type nitride semiconductor layer formed on the substrate; an active layer formed on the p-type nitride semiconductor layer, the active layer including a plurality of quantum barrier layers and a plurality of quantum well layers deposited alternately on each other; an n-type nitride semiconductor layer formed on the active layer; a p-electrode formed on a bottom of the substrate; and an n-electrode formed on a top of the n-type nitride semiconductor layer.

The substrate may be a p-type GaN substrate. Thep-type GaN substrate may have a doping concentration of 1×10¹⁷ to 9×10¹⁹/cm³. The p-type GaN substrate may have a thickness of about 50 to 100 nm, thereby inducing less electrical resistance.

The p-type nitride semiconductor layer may include a p-type AlGaN layer formed on the substrate to have an interface contacting the active layer. The p-type nitride semiconductor layer may include a p-type GaN layer formed on an interface contacting a top of the substrate. Also, among the quantum barrier layers, a quantum barrier layer having an interface contacting the p-type AlGaN layer may be formed of an undoped GaN layer. The undoped GaN layer may have a thickness of 2 to 10 nm.

The n-type nitride semiconductor layer may be formed of n-type GaN. The n-type nitride semiconductor layer may have a thickness of 2 to 500 nm considering electrical resistance and tunneling effects.

The nitride semiconductor light emitting device may further include a reflective metal layer formed between the substrate and the p-electrode.

According to another aspect of the present invention, there is provided a method of manufacturing a nitride semiconductor light emitting device, the method including: providing a substrate for growing a nitride single crystal, the substrate having electrical conductivity; growing a p-type nitride semiconductor layer on the substrate; growing an active layer on the p-type nitride semiconductor layer, the active layer including a plurality of quantum barrier layers and a plurality of quantum well layers deposited alternately on each other; growing an n-type nitride semiconductor layer on the active layer; forming a p-electrode on a bottom of the substrate; and forming an n-electrode on a top of the n-type nitride semiconductor layer.

The p-type nitride semiconductor layer may be grown at a temperature of 950□ or higher, particularly, 1000 to 1200□ to ensure excellent crsytallinity. Also, the un-doped GaN layer may be grown at a temperature of 950□ or higher.

The p-type nitride semiconductor layer maybe directly heat-treated in a reactor, thereby simplified in the heat treatment process.

The method may further include: polishing the substrate to a smaller thickness after all of the layers are grown. The polishing the substrate may be performed after the forming an n-electrode and before the forming a p-electrode.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A through 1C are procedural side cross-sectional views for explaining a method of manufacturing a conventional nitride semiconductor light emitting device;

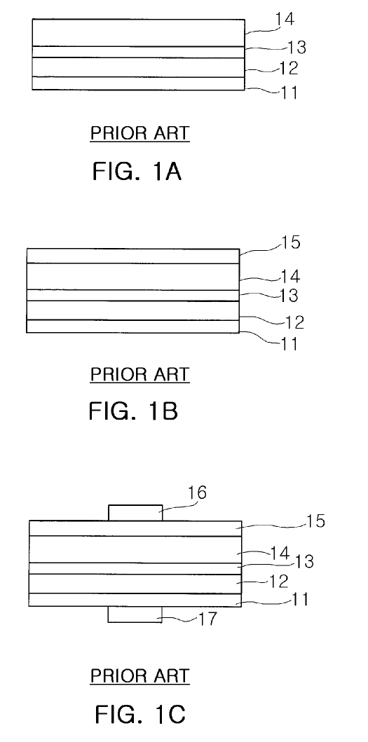

FIGS. 2A and 2B are side cross-sectional views illustrating a nitride semiconductor light emitting device according to an exemplary embodiment of the invention; and

FIGS. 3A through 3F are procedural side cross-sectional views for explaining a method of manufacturing a nitride semiconductor light emitting device according to an exemplary embodiment of the invention.

### DETAILED DESCRIPTION OF THE PREFERRED EMBODIMENT

Exemplary embodiments of the present invention will now be described in detail with reference to the accompanying drawings.

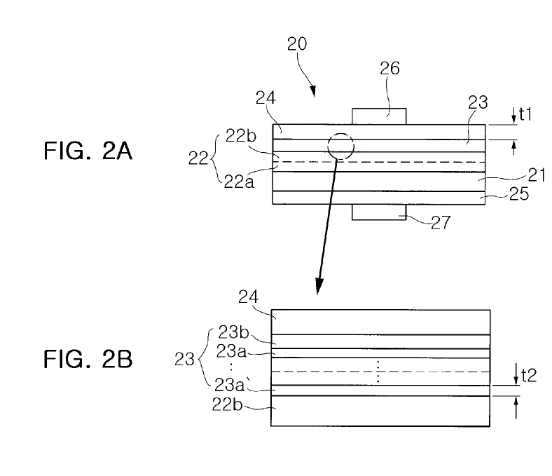

FIGS. 2A and 2B are side cross-sectional views illustrating a nitride semiconductor light emitting device according to an exemplary embodiment of the invention.

As shown in FIG. 2A, the nitride semiconductor light emitting device 20 of the present embodiment includes an electrically conductive substrate 21 for growing a nitride single crystal, a p-type nitride semiconductor layer 22 formed on the substrate, an active layer 23 formed on the p-type nitride semiconductor layer 22 and including a plurality of quantum barrier layers and a plurality of quantum well layers deposited alternately on each other, an n-type nitride semiconductor layer 24 formed on the active layer, a p-electrode 27 formed on a bottom of the nitride single crystal growth substrate 21 and an n-electrode 26 formed on a top of the n-type nitride semiconductor layer 24.

Here, the p-type nitride semiconductor layer 22 may include a p-type AlGaN layer 22b formed on the substrate 21 to have an interface contacting the active layer. Also, the p-type nitride semiconductor layer 22 may include a p-type GaN layer 22a having an interface contacting a top of the substrate 21 to reduce a contact resistance with respect to the substrate 21.

According to the present embodiment, the n-type nitride semiconductor layer 24 may be formed of n-type GaN. The n-type nitride semiconductor layer 24 may have a thickness t1 of 2 to 500 nm. Therefore, the n-type nitride semiconductor layer 24 with such a small thickness can be manufactured with less time, thereby saving manufacturing time of the nitride semiconductor light emitting device.

Additionally, a reflective metal layer 25 may be disposed between the nitride single crystal growth substrate 21 and the p-electrode 27.

FIG. 2B is a magnified side cross-sectional view illustrating the active layer 23 shown in FIG. 2A. Referring to FIG. 2B, the active layer 23 includes a plurality of quantum well layers 23b and quantum barrier layers 23a deposited alternately on each other. Among the quantum barrier layers 23a of the active layer, a quantum barrier layer having an interface contacting the p-type AlGaN layer 22b may be formed of an undoped GaN 23a′ layer, which prevents migration of Al atoms. Here, the undoped GaN layer 23a′ may have a thickness t2 of 2 to 10 nm.

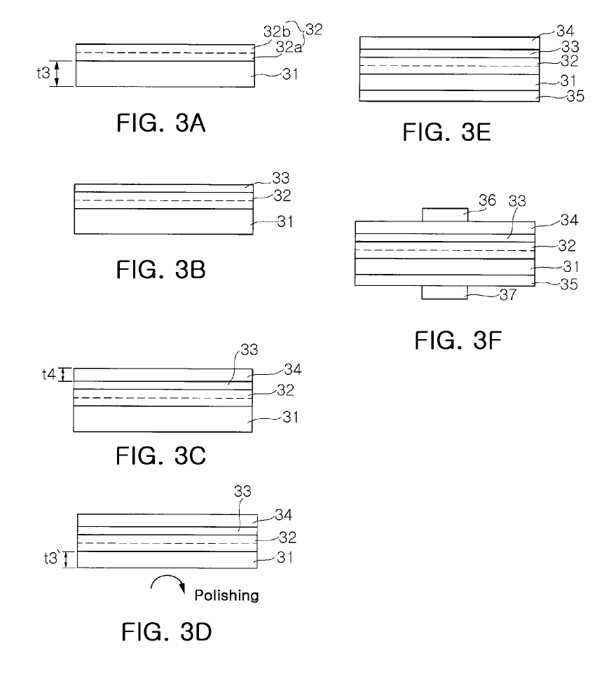

FIGS. 3A through 3G illustrate a method of manufacturing a nitride semiconductor light emitting device structured as above according to an exemplary embodiment of the invention.

First, as shown in FIG. 3A, a p-type nitride semiconductor layer 32 is formed on an electrically conductive substrate 31 for growing a nitride single crystal. Typically, the substrate 31 may have a thickness t3 of hundreds of W.

Also, as described above, the p-type nitride semiconductor layer 32 may include a p-type AlGaN layer 32b and a p-type GaN layer 32a. Here, to improve crystallinity and optical properties of a nitride semiconductor light emitting device through high-temperature growth, the p-type nitride semiconductor layer 32 may be grown at a temperature of 950□ or higher, particularly, 1000 to 1200□.

Then, the grown p-type nitride semiconductor layer 32 is heat-treated to activate dopant atoms. Here, the p-type nitride semiconductor layer 32 may be directly heat-treated in a reactor and thus simplified in the process over conventional heat treatment by an additional RTA equipment after all nitride layers are grown. Furthermore, the p-type nitride semiconductor layer 32 is heat-treated before an active layer 33 is grown as shown in FIG. 3B. This prevents the dopant atoms from migrating to the active layer 33, while causing less heat-induced damage to the active layer.

Thereafter, as shown in FIG. 3B, the active layer 33 is formed on the p-type nitride semiconductor layer 32. The active layer 33 may be structured as in FIG. 2B. In this structure, among quantum barrier layers 23a of the active layer 33, a quantum barrier layer having an interface contacting the p-type AlGaN layer 22b is grown as an undoped GaN layer 23a, and a plurality of quantum well layers 23b and quantum barrier layers 23a are deposited alternatively on each other on the undoped GaN layer 23a. Here, the undoped GaN layer 23a may be grown at a temperature of 950□ or higher, thereby improving crystallinity and optical properties of the nitride semiconductor light emitting device.

Subsequently, as shown in FIG. 3C, an n-type nitride semiconductor layer 34 is formed on the active layer 33. The n-type nitride semiconductor layer 34 may have a thickness t1 of about 2 to 500 nm. The n-type nitride semiconductor layer 34 even with the thickness as small as just described ensures sufficient crsytallinity unlike a case where the n-type nitride semiconductor layer 34 is grown on the substrate. This thickness range is the one considering electrical resistance and tunneling effects. Accordingly, the n-type nitride semiconductor layer with such a small thickness can be grown in a much shorter time, e.g., about at least 1000 times shorter than a conventional n-type nitride semiconductor layer grown to a thickness of several

Next, as shown in FIG. 3D, after all of the nitride layers are grown, the substrate 31 may be polished. The polishing may be carried out by a chemical or mechanical method. The polishing allows the substrate 31 to have a thickness t3′ of about 50 to 10 nm. This thickness range is based on a consideration that a total thickness of the substrate 31 and the p-type nitride layer 32 may rang from 150 to 200 nm in view of reflection effects and electrical resistance effects.

As described above, the substrate with a smaller thickness may induce less electrical resistance than the conventional one with a thickness of hundreds of μm.

In addition, although not shown, the substrate may be polished, after an n-electrode 36 is formed and before a p-electrode 37 is formed as described in FIG. 3F.

Afterwards, as shown in FIG. 3F, a reflective metal layer 35 may be formed on a bottom of the nitride single crystal growth substrate 31.

Finally, as shown in FIG. 3F, the p-electrode 37 is formed on a bottom of the reflective metal layer 35 and the n-electrode 36 is formed on a top of the n-type nitride semiconductor layer 34. In a case where the formation of the reflective metal layer 35 as described in FIG. 3E is omitted, the p-electrode 37 is directly formed on the bottom of the nitride single crystal growth substrate 31.

As set forth above, according to exemplary embodiments of the invention, a p-type nitride semiconductor layer is grown before formation of an active layer. This prevents dopant atoms from migrating to the active layer, thereby allowing heat treatment to be carried out at a high temperature of 950□. This accordingly improves crystallinity and optical properties of a nitride semiconductor light emitting device over a case where an n-type GaN substrate is employed. Moreover, a p-type nitride semiconductor layer is directly heat-treated in a reactor, thereby simplified in the heat treatment process.

Moreover, an n-type nitride semiconductor layer is grown to a small thickness of about 2 to 500 nm, thereby reducing overall manufacturing time over a conventional method.

While the present invention has been shown and described in connection with the exemplary embodiments, it will be apparent to those skilled in the art that modifications and variations can be made without departing from the spirit and scope of the invention as defined by the appended claims.

1-11. (canceled)

12. A method of manufacturing a nitride semiconductor light emitting device, the method comprising:
providing a substrate for growing a nitride single crystal, the substrate having electrical conductivity;
growing a p-type nitride semiconductor layer on the substrate;
growing an active layer on the p-type nitride semiconductor layer, the active layer comprising a plurality of quantum barrier layers and a plurality of quantum well layers deposited alternately on each other;
growing an n-type nitride semiconductor layer on the active layer;
forming a p-electrode on a bottom of the substrate; and
forming an n-electrode on a top of the n-type nitride semiconductor layer.

13. The method of claim 12, wherein the substrate is a p-type GaN substrate.

14. The method of claim 13, wherein the p-type GaN substrate has a doping concentration of 1×10¹⁷ to 9×10¹⁹/cm³.

15. The method of claim 13, wherein the p-type GaN substrate has a thickness of about 50 to 100 nm.

16. The method of claim 12, wherein the p-type nitride semiconductor layer comprises a p-type AlGaN layer formed on the substrate to have an interface contacting the active layer.

17. The method of claim 16, wherein the p-type nitride semiconductor layer comprises a p-type GaN layer formed on an interface contacting a top of the substrate.

18. The method of claim 16, wherein among the quantum barrier layers, a quantum barrier layer having an interface contacting the p-type AlGaN layer is formed of an undoped GaN layer.

19. The method of claim 18, wherein the undoped GaN layer has a thickness of 2 to 10 nm.

20. The method of claim 12, wherein the n-type nitride semiconductor layer is formed of n-type GaN.

21. The method of claim 12, wherein the n-type nitride semiconductor layer has a thickness of 2 to 500 nm.

22. The method of claim 12, further comprising: forming a reflective metal layer between the substrate and the p-electrode.

23. The method of claim 12, wherein the p-type nitride semiconductor layer is grown at a temperature of 950° C. or higher.

24. The method of claim 12, wherein the p-type nitride semiconductor layer is grown at a temperature of 1000 to 1200° C.

25. The method of claim 12, wherein the un-doped GaN layer is grown at a temperature of 950° C. or higher.

26. The method of claim 12, wherein the p-type nitride semiconductor layer is directly heat-treated in a reactor.

27. The method of claim 12, further comprising: polishing the substrate after all of the layers are grown.

28. The method of claim 12, wherein the polishing the substrate is performed after the forming an n-electrode and before the forming a p-electrode.
